(19) United States
(12) Patent Application Publication
(10) Pub. No.: US 2015/0043270 A1
(43) Pub. Date: Feb. 12, 2015

(54) MEMORY CELL HAVING BUILT-IN WRITE ASSIST

(71) Applicant: LSI CORPORATION, SAN JOSE, CA (US)

(72) Inventors: Sahilpreet Singh, Bangalore (IN); Anjana Das, Bangalore (IN)

(73) Assignee: LSI CORPORATION, SAN JOSE, CA (US)

(21) Appl. No.: 14/227,132

(22) Filed: Mar. 27, 2014

(30) Foreign Application Priority Data
Aug. 8, 2013 (IN) 3561/CHE/2013

(51) Int. Cl. G11C 11/416

(52) U.S. Cl. CPC G11C 11/416
USPC 365/154

(57) ABSTRACT

A memory cell includes a storage element including a pair of cross-coupled inverters, and first switching circuitry for selectively connecting at least one internal storage node of the storage element with a corresponding bit line as a function of a first control signal. Write assist circuitry is connected between a supply node of a device of at least one of the cross-coupled inverters and a voltage supply of the memory cell, and second switching circuitry selectively couples the supply node of the device of at least one of the cross-coupled inverters with the corresponding bit line as a function of a second control signal. During a write operation, the write assist circuitry disconnects the storage element from the voltage supply, and the second circuitry connects the supply node of the device of at least one of the cross-coupled inverters with the corresponding bit line.

### CROSS-REFERENCE TO RELATED APPLICATIONS

This application claims priority under 35 U.S.C. §119 from Indian Patent Application No. 3561/CHE/2013 filed in the Indian Patent Office on Aug. 8, 2013, the disclosure of which is incorporated herein by reference in its entirety.

### TECHNICAL FIELD

The present invention relates generally to electrical and electronic circuitry, and more particularly relates to semiconductor memory devices.

### BACKGROUND

A memory device is typically comprised of memory cells arranged in an array of rows and columns, with each memory cell storing one or more bits of data. Memory cells within a given row of the array are connected to a common word line, while memory cells within a given column of the array are connected to a common bit line. Each of the memory cells in the array is coupled to a unique pair of a corresponding bit line and word line for selectively accessing the memory cells.

Traditionally, in the context of static random access memory (SRAM), six-transistor (6T) SRAM cells may be employed. Unlike dynamic random access memory (DRAM) cells, SRAM cells have the ability to hold data without requiring refreshing, and are therefore advantageous. However, as transistor geometries continue to shrink, it becomes increasingly more difficult to prevent local mismatch between the transistors forming the memory cells. This mismatch can adversely affect memory device performance, including, for example, the ability to consistently write data to the memory cells at low voltages (e.g., about one volt or less). To further exacerbate this problem, there has been a trend to reduce operating voltages of memory circuits, thereby reducing read and write margins of the SRAM cells which measure how reliably data can be read from and written to the SRAM cells, respectively. Due to the existence of static noise, among other factors, the reduced read and write margins may introduce errors in the respective read and write operations.

### SUMMARY

In accordance with an embodiment of the invention, a memory cell includes a storage element for storing a logical state of the memory cell, the storage element including a pair of cross-coupled inverters configured as a latch, and first switching circuitry operative to selectively couple at least one internal storage node of the storage element with a corresponding bit line as a function of a first control signal. The memory cell further includes write assist circuitry coupled between a supply node of a device of at least one of the cross-coupled inverters in the storage element and a voltage supply of the memory cell, and second switching circuitry operative to selectively couple the supply node of the device of at least one of the cross-coupled inverters in the storage element with the corresponding bit line as a function of a second control signal. During a write operation of the memory cell, the write assist circuitry is operative to disconnect the storage element from the voltage supply of the memory cell and the second circuitry is operative to connect the supply node of the device of at least one of the cross-coupled inverters with the corresponding bit line.

In accordance with another embodiment of the invention, a memory device includes a plurality of memory cells, at least one word line and a plurality of bit lines, the word line and bit lines being coupled with the memory cells for individually accessing the memory cells. At least a given one of the memory cells includes a storage element for storing a logical state of the memory cell, and first switching circuitry operative to selectively couple at least one internal storage node of the storage element with a corresponding one of the bit lines as a function of a first control signal. The at least one memory cell further includes write assist circuitry coupled between a supply node of at least one device of the storage element and a voltage supply of the memory cell, and second switching circuitry operative to selectively couple the supply node of the at least one device of the storage element with the corresponding one of the bit lines as a function of a second control signal. During a write operation of the memory cell, the write assist circuitry is operative to disconnect the storage element from the voltage supply of the memory cell and the second circuitry is operative to connect the supply node of the at least one device of the storage element with the corresponding bit line

In accordance with another embodiment of the invention, a method for enhancing write performance in a memory cell includes: providing at least one memory cell comprising a storage element for storing a logical state of the memory cell, first switching circuitry operative to selectively couple at least one internal storage node of the storage element with a corresponding bit line as a function of a first control signal, write assist circuitry coupled between a supply node of at least one device of the storage element and a voltage supply of the memory cell, and second switching circuitry operative to selectively couple the supply node of the at least one device of the storage element with the corresponding bit line as a function of a second control signal; and, during a write operation of the memory cell, configuring the write assist circuitry to disconnect the storage element from the voltage supply of the memory cell and configuring the second circuitry to connect the supply node of the at least one device of the storage element with the corresponding bit line.

Embodiments of the invention will become apparent from the following detailed description thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 schematically depicts an illustrative memory device in which one or more aspects of the invention can be employed, in the context of the present disclosure;

FIG. 2 schematically depicts an illustrative single-port SRAM cell suitable for use in the exemplary memory device shown in FIG. 1;

FIG. 3 is a schematic diagram depicting at least a portion of an exemplary SRAM cell with built-in write assist functionality, according to an embodiment of the invention;

FIG. 4 is a schematic diagram depicting at least a portion of an exemplary SRAM cell with built-in write assist functionality, according to an embodiment of the invention;

FIG. 5 is graph depicting exemplary waveforms corresponding to certain signals in the illustrative SRAM cell shown in FIG. 4, according to an embodiment of the invention;

FIG. 6 is a schematic diagram depicting at least a portion of an exemplary SRAM memory cell with built-in write assist functionality, according to another embodiment of the invention;

FIG. 7 is a schematic diagram depicting at least a portion of an SRAM cell with built-in write assist functionality adapted for use in a dual-port memory architecture, according to an embodiment of the invention;

FIG. 8 is a schematic diagram depicting at least a portion of an SRAM cell with built-in write assist functionality adapted for use in a dual-port memory architecture, according to another embodiment of the invention;

FIG. 9 is a block diagram depicting at least a portion of an exemplary processing device which incorporates the illustrative memory device shown in FIG. 1, according to an embodiment of the invention; and

FIG. 10 is a block diagram depicting at least a portion of an exemplary processor integrated circuit incorporating the illustrative memory device shown in FIG. 1 as an embedded memory, according to an embodiment of the invention.

It is to be appreciated that the drawings described herein are presented for illustrative purposes only. Moreover, common but well-understood elements and/or features that may be useful or necessary in a commercially feasible embodiment may not be shown in order to facilitate a less hindered view of the illustrated embodiments.

### DETAILED DESCRIPTION

Embodiments of the invention will be described herein in the context of illustrative SRAM circuits and associated SRAM cells with write assist. It should be understood, however, that embodiments of the invention are not limited to these or any other particular circuit arrangements. Rather, embodiments of the invention are more broadly applicable to any memory system, single-port or multi-port, in which improved low-voltage write performance is desired, without concern for whether the memory is embedded or standalone. In this regard, embodiments of the invention provide a write assist scheme that beneficially reduces memory cycle time in a variety of memory arrangements and types, such as, for example, random access memory (RAM), SRAM, content addressable memory (CAM), flash memory, memory caches, register files, port buffer memories, and the like, without significantly increasing semiconductor area of the memory. Moreover, it will become apparent to those skilled in the art given the teachings herein that numerous modifications can be made to the illustrative embodiments shown that are within the scope of the claimed invention. That is, no limitations with respect to the embodiments shown and described herein are intended or should be inferred.

As a preliminary matter, for purposes of clarifying and describing embodiments of the invention, the following table provides a summary of certain acronyms and their corresponding definitions, as the terms are used herein:

Table of Acronym Definitions

| Acronym | Definition |
|---|---|
| SRAM | Static random access memory |
| 6T | Six-transistor |
| RAM | Random access memory |
| CAM | Content addressable memory |
| MISFET | Metal-insulator-semiconductor field-effect transistor |
| MOSFET | Metal-oxide-semiconductor field-effect transistor |
| FET | Field-effect transistor |
| NFET | N-channel field-effect transistor |
| NMOS | N-channel metal-oxide-semiconductor |
| PFET | P-channel field-effect transistor |
| PMOS | P-channel metal-oxide-semiconductor |
| CMOS | Complementary metal-oxide-semiconductor |
| MOS | Metal-oxide-semiconductor |
| BJT | Bipolar junction transistor |
| SNM | Static noise margin |
| RNM | Retention noise margin |
| WM | Write margin |
| WT | Write time |

Throughout the description herein, the term MISFET is intended to be construed broadly and to encompass any type of metal-insulator-semiconductor field-effect transistor. The term MISFET is, for example, intended to encompass semiconductor field-effect transistors (FETs) that utilize an oxide material as their gate dielectric (i.e., metal-oxide-semiconductor field-effect transistors (MOSFETs)), as well as those that do not. In addition, despite a reference to the term “metal” in the acronym MISFET, the term MISFET is intended to encompass semiconductor field-effect transistors wherein the gate is formed from a non-metal, such as, for instance, polysilicon.

Although embodiments of the invention described herein may be implemented using p-channel MISFETs (hereinafter called “PFETs” or “PMOS” devices) and/or n-channel MISFETs (hereinafter called “NFETs” or “NMOS” devices), as may be formed using a complementary metal-oxide-semiconductor (CMOS) fabrication process, it is to be appreciated that embodiments of the invention are not limited to such transistor devices and/or such a fabrication process, and that other suitable devices, such as, for example, bipolar junction transistors (BJTs), FinFETs, etc., and/or fabrication processes (e.g., bipolar, BiCMOS, etc.), may be similarly employed, as will be understood by those skilled in the art. Moreover, although embodiments of the invention are typically fabricated in a silicon wafer, embodiments of the invention can alternatively be fabricated in wafers comprising other materials, including but not limited to gallium arsenide (GaAs), indium phosphide (InP), etc.

Many modern high-speed memories, including, but not limited to, caches, register files, port buffer memories, content addressable memories (CAMs), etc., demand single-port and multi-port SRAMs having fast write times. There are several known circuits and architectural techniques for speeding up write time in the memory/register file with a capability to speed up data flow through logic circuitry in the memory/register file. Write time is often determined as a sum of the time to assert an enable signal on a selected word line and the time to transfer data to be written to a selected memory cell from a corresponding bit line. Write time is a critical timing parameter that limits the cycle time of memory devices.

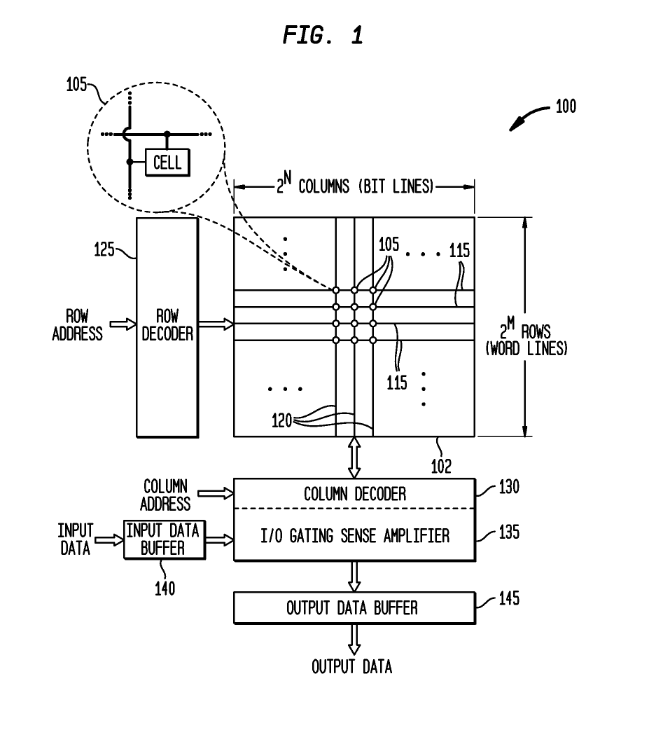

FIG. 1 schematically depicts an illustrative memory device 100 in which one or more aspects of the invention can be employed, in the context of the present disclosure. The memory device 100 includes a memory array 102 comprising a plurality of memory cells 105, each of the memory cells being configured to store data. Each memory cell 105 in a given row is coupled with a corresponding common word line 115, and each cell in a given column is coupled with a corresponding common bit line 120, such that the memory array 102 includes a memory cell 105 at each intersection of a word line 115 and a bit line 120. In this illustrative embodiment, the memory array 102 is organized having 2^{M} rows and 2^{N} columns, where M and N are integers. The values of M and N will depend upon the particular data storage requirements of the application in which the memory device 100 is used; embodiments of the invention are not limited to any specific values for M and N.

The memory cells 105 in memory device 100 can be individually accessed for writing data thereto (e.g., during a write operation) or reading data therefrom (e.g., during a read operation) by activation of appropriate row and column addresses to row decoder 125 and column decoder 130, respectively. The memory device 100 includes additional circuitry for facilitating the read and write operations, including, for example, an input/output (I/O) gating sense amplifier 135, input data buffers 140, and output data buffers 145.

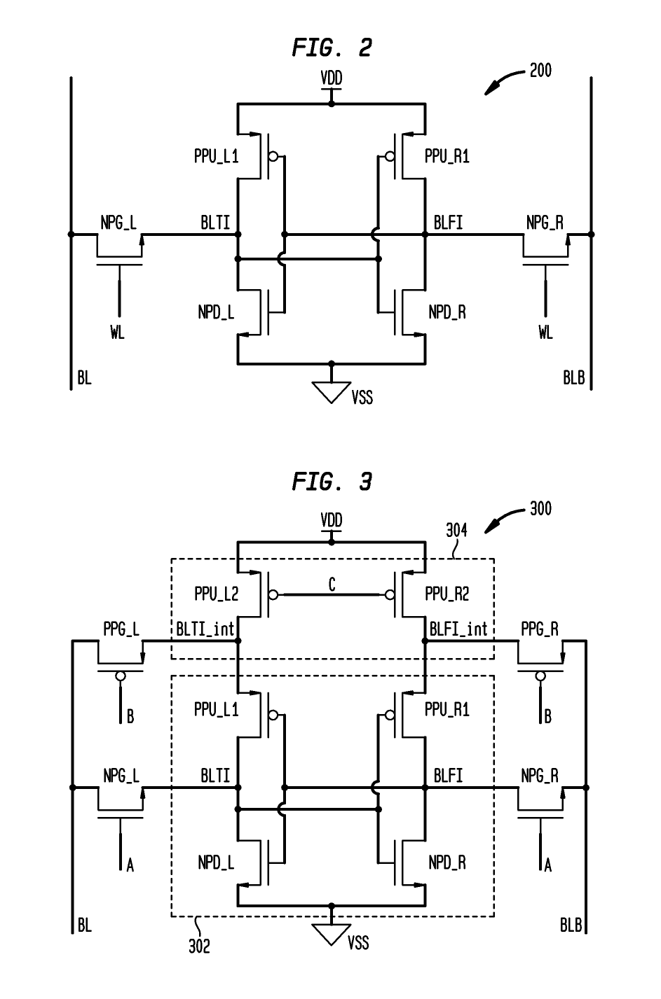

FIG. 2 schematically depicts an illustrative single-port SRAM cell 200 suitable for use in the exemplary memory device 100 shown in FIG. 1, in the context of the present disclosure. The SRAM cell 200 includes one word line (WL) and a pair of complementary bit lines (BL/BLB) coupled to the cell for accessing the cell (e.g., reading and writing). In SRAM cell 200, there is no read assist or write assist employed. The SRAM cell 200 is implemented, in this example, as a 6T SRAM cell, although it is to be appreciated that embodiments of the invention are not limited to 6T SRAM cells.

The illustrative SRAM cell 200 includes first and second NFETs, NPG_L and NPG_R, operative as switching devices (e.g., pass gates), and a pair of cross-coupled inverters operative as a storage element (e.g., latch) for the SRAM cell. Specifically, a first inverter includes a PFET, PPU_L1, and an NFET, NPD_L, and a second inverter includes a PFET, PPU_R1, and an NFET, NPD_R. A drain of NPG_L is coupled with bit line BL, which may be a true bit line, a gate of NPG_L is coupled with the word line WL, and a source of NPG_L is connected with drains of PPU_L1 and NPD_L at node BLTI. Sources of PPU_L1 and PPU_R1 are connected with a voltage supply, which is VDD in this embodiment, sources of NPD_L and NPD_R are connected with a voltage return, which is VSS in this embodiment, gates of PPU_L1 and NPD_L are connected with drains of PPU_R1 and NPD_R at node BLFI, and gates of PPU_R1 and NPD_R are connected to node BLTI. A gate of NPG_R is coupled with the word line WL, a drain of NPG_R is connected with node BLFI, and a source of NPG_R is coupled with bit line BLB, which may be a complement bit line.

It is to be appreciated that, because a MISFET device is symmetrical in nature, and thus bi-directional, the assignment of source and drain designations in the MISFET device is essentially arbitrary. Therefore, the source and drain of a given MISFET device may be referred to herein generally as first and second source/drain, respectively, where “source/drain” in this context denotes a source or a drain.

Several parameters can be used to evaluate the performance of a memory cell, including, but not limited to, static noise margin (SNM), retention noise margin (RNM), write margin (WM) and write time (WT). Static noise margin, which affects both read margin and write margin, is related to threshold voltages of the NFET and PFET devices in the SRAM cell. (See, e.g., Debasis Mukherjee et al., “Static Noise Margin Analysis of SRAM Cell for High Speed Application,” International Journal of Computer Science Issues, vol. 7, issue 5, pp. 175-180, September 2001, the disclosure of which is incorporated herein by reference in its entirety.) Write margin corresponds to a minimum voltage difference between the bit lines which still enables writing to be performed in the SRAM cell. Retention noise margin is indicative of the static noise margin of the SRAM cell with the word line not selected (e.g., when WL is a logic low level in this embodiment). In other words, the RNM of the SRAM cell 200 corresponds to a difference between voltages on the internal nodes, BLTI and BLFI, and a failure threshold for those voltages when the memory cell is retaining data. Write time is indicative of a time delay between the availability of data on the bit lines BL/BLB to be written into the SRAM cell 200 and activation of the corresponding word line WL coupled with the SRAM cell. Often, by improving one SRAM cell parameter, another cell parameter is degraded. For example, SNM and WM are complementary to one another, and thus if SNM is improved, WM worsens, and vice versa. To increase SNM, the threshold voltages of the NFET and PFET devices in the SRAM cell can be altered. However, for applications in which reduced operating voltages are desired, altering the threshold voltages of the NFET and PFET devices would have a detrimental impact on SRAM cell performance. More particularly, when the respective threshold voltages of the NFET and PFET devices are altered to improve the SNM, it will degrade the WM, and vice versa. Consequently, in accordance with one or more embodiments of the invention, the threshold voltages of NFET and/or PFET devices in the SRAM memory cell are configured so as to achieve a prescribed balance between WM and SNM, which ultimately will determine an overall performance of the SRAM cell.

With increasing pressure to reduce operating voltages in memory systems, WM and WT have become parameters of keen interest in SRAM cell designs, as these parameters tend to degrade considerably with decreasing supply voltage. Accordingly, it is known to employ write assist techniques for use in conjunction with SRAM cells. In a write assist methodology, Memory designers often optimize the SRAM cell for increased SNM at the expense of WM, and then improve WM in the cell using write assist techniques. However, for certain applications, such as, for example, high-speed register files, conventional write assist techniques, which generally utilize capacitive charge pump based circuitry, significantly increase area and/or complexity of the memory device and are therefore not preferred.

FIG. 3 is a schematic diagram depicting at least a portion of an exemplary SRAM cell 300 with built-in write assist functionality, according to an embodiment of the invention. Like the SRAM cell 200 shown in FIG. 2, SRAM cell 300 includes a storage element 302 comprised of a pair of cross-coupled inverters, and first switching circuitry comprising first and second NFETs, NPG_L and NPG_R, operative as pass gate devices, for selectively connecting the storage element to respective complementary bit lines BL and BLB. More particularly, a first inverter includes PFET PPU_L1 and NFET NPD_L, and a second inverter includes PFET PPU_R1 and NFET NPD_R. A drain of NPG_L is coupled with bit line BL, a gate of NPG_L is adapted to receive a first control signal at node A, and a source of NPG_L is connected with drains of PPU_L1 and NPD_L at node BLTI. Sources of NPD_L and NPD_R are adapted for connection with VSS, gates of PPU_L1 and NPD_L are connected with drains of PPU_R1 and NPD_R at node BLFI, and gates of PPU_R1 and NPD_R are connected to node BLTI. A gate of NPG_R is connected with node A and is adapted to receive the first control signal, a drain of NPG_R is connected with node BLFI, and a source of NPG_R is coupled with bit line BLB. Thus, when the first control signal is at a logic high level (e.g., VDD), the internal storage nodes BLTI and BLFI in storage element 302 are connected to corresponding bit lines BL and BLB through pass gates NPG_L and NPG_R, respectively. Likewise, when the first control signal is at a logic low level (e.g., VSS), devices NPG_L and NPG_R turn off, thereby electrically disconnecting the storage element 302 from the bit lines BL and BLB.

The SRAM cell 300 further includes write assist circuitry 304 connected between the storage element 302 (specifically, a voltage supply node of a device of at least one of the cross-coupled inverters in the storage element 302) and the voltage supply of the SRAM cell, which in this embodiment is VDD, and second switching circuitry comprising first and second PFETs, PPG_L and PPG_R, operative as pass gate devices, for selectively connecting the write assist circuitry to respective complementary bit lines BL and BLB. In this embodiment, the write assist circuitry 304 comprises a pair of PFET devices, PPU_L2 and PPU_R2, although embodiments of the invention are not limited to the particular circuit arrangement shown. Specifically, a drain of PPG_L is connected with bit line BL, a gate of PPG_L is adapted to receive a second control signal at node B, and a source of PPG_L is connected with a source of PPU_L1 and a drain of PPU_L2 at node BLTI_int. A drain of PPG_R is connected with bit line BLB, a gate of PPG_R is connected with node B and is adapted to receive the second control signal, and a source of PPG_R is connected with a source of PPU_R1 and a drain of PPU_R2 at node BLFI_int. Sources of PPU_L2 and PPU_R2 are adapted for connection with VDD, and gates of PPU_L2 and PPU_R2 are adapted to receive a third control signal at node C. Although shown as being separate from the write assist circuitry 304, the second switching circuitry may, in one or more embodiments, be incorporated into the write assist circuitry.

When the second control signal is at a logic low level (e.g., VSS), transistors PPG_L and PPG_R turn on, and nodes BLTI_int and BLFI_int which form a junction between storage element 302 and write assist circuitry 304, are connected to respective bit lines BL and BLB. Likewise, when the second control signal is at a logic high level (e.g., VDD), transistors PPG_L and PPG_R turn off, thereby electrically disconnecting nodes BLTI_int and BLFI_int from the respective bit lines BL and BLB. When the third control signal is at a logic low level, devices PPU_L2 and PPU_R2 turn on, thereby connecting the storage element 302 at nodes BLTI_int and BLFI_int to VDD. Similarly, when the third control signal is at a logic high level, transistors PPU_L2 and PPU_R2 turn off, thereby electrically disconnecting nodes BLTI_int and BLFI_int, and hence disconnecting the storage element 302, from VDD.

SRAM cell 300 includes ten transistors and may therefore be referred to herein as a 10T SRAM cell. This 10T SRAM cell is a single-port cell having write assist and gated read functionality, and is adapted for use in a single-port memory device/system. It is to be appreciated, however, that in accordance with embodiments of the invention, the number of transistors employed in the memory cell will be dependent upon the type of cell required for a particular application. For example, a twelve-transistor (12T) SRAM cell implementation having write assist and dedicated ports for reading (using pass gates) and writing can be utilized in a dual-port memory device/system. This 12T SRAM cell version is adapted to receive separate read and write complementary bit lines and separate read and write complementary word lines. In a single-ended read bit line memory device/system, a fourteen-transistor (14T) implementation of the SRAM cell can be used, as will be described in further detail herein below. Other SRAM versions incorporating one or more aspects according to embodiments of the invention are similarly contemplated, as will become apparent to those skilled in the art given the teachings herein.

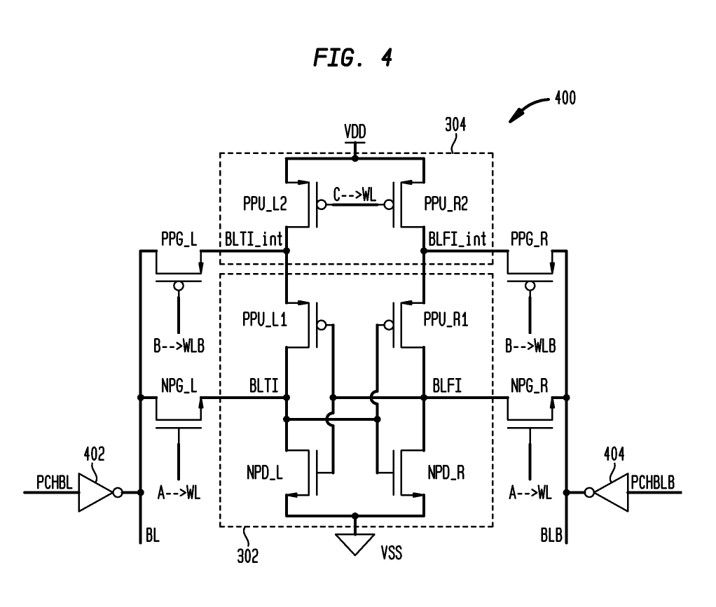

With reference now to FIG. 4, a schematic diagram depicts at least a portion of an exemplary SRAM cell 400 with built-in write assist functionality, according to an embodiment of the invention. As apparent from FIG. 4, SRAM cell 400 is essentially the same circuit topology as the exemplary SRAM cell 300 shown in FIG. 3, except that connections to nodes A, B and C are depicted, in accordance with an illustrative embodiment of the invention. Specifically, node A is connected with a corresponding word line, WL, node B is connected with a logical complement (i.e., a logical inversion) of the word line, WLB, and node C is also connected with word line WL.

Also depicted in FIG. 4 is a bit line precharge circuit, which in this embodiment is comprised of a pair of inverters, 402 and 404, connected with respective complementary bit lines BL and BLB. The bit line precharge circuit is not necessarily part of the SRAM cell 400, but rather is preferably included, along with the bit lines, word lines, etc., as part of the overall memory device in which the SRAM cell is utilized. Inverter 402 is adapted to receive, at an input thereof, a first bit line precharge control signal, PCHBL, supplied by the memory device, and is operative to generate, at an output thereof, a first precharge signal which is a logical inversion of the first precharge control signal. Likewise, inverter 404 is adapted to receive, at an input thereof, a second bit line precharge control signal, PCHBLB, supplied by the memory device, and is operative to generate, at an output thereof, a second precharge signal which is a logical inversion of the second precharge control signal. In one or more embodiments, the first and second precharge control signals PCHBL and PCHBLB, respectively, are at a logic low level (e.g., VSS) during a precharge mode of operation of the memory device, and thus the bit lines BL and BLB are precharged to a logic high level (e.g., VDD).

In terms of operation, during a default (i.e., initial) state of the SRAM cell 400, such as when the cell is not being accessed in conjunction with a read or write operation, the word line WL will be at a logic low level (i.e., de-asserted) and the complementary bit lines BL and BLB will be precharged to a logic high level (e.g., VDD), in this example. With the word line WL at a logic low level (e.g., VSS), the complementary word line WLB will be at a logic high level. Accordingly, NFET devices NPG_L and NPG_R will be turned off, thereby disconnecting the internal storage nodes BLTI and BLFI from the bit lines BL and BLB, respectively. Moreover, PFET devices PPU_L2 and PPU_R2 will be turned on, and PFET devices PPG_L and PPG_R will be turned off, thereby allowing nodes BLTI_int and BLFI_int to be pulled high (e.g., VDD).

During a write “0” operation, at the start of the write operation, the precharge control signal PCHBL will be de-asserted (i.e., PCHBL will go high), thereby forcing the bit line BL low (e.g., VSS). Substantially concurrently, the word lines WL and WLB are asserted by setting WL high and WLB low, thereby turning on pass gate transistors NPG_L, NPG_R, PPG_L and PPG_R, and turning off pull-up transistors PPU_L2 and PPU_R2. With PPU_L2 and PPU_R2 turned off, the storage element 302 (particularly, transistors PPU_L1 and PPU_R1) is effectively disconnected from the voltage supply VDD. With PPG_L turned on and PPU_L2 turned off, the node BLTI_int will begin discharging to VSS through pass gate PPG_L. Once the voltage at node BLTI_int falls below about a PMOS transistor threshold voltage (Vtp) above VSS, transistor PPU_L1 in the storage element 302 will completely turn off, thereby causing the internal storage node BLTI to float, since there will be no current flowing through transistors PPU_L1 and NPD_L.

With regard to the other half of the latch forming storage element 302, bit line BLB, being a logical complement of bit line BL, is set to a logic high level and, with the complementary word line WLB at a low level, pass gate transistor PPG_R will be turned on. Accordingly, node BLFI_int will remain pulled up to VDD through transistor PPG_R for supplying power to the inverter comprising transistors PPU_R1 and NPD_R.

Since bit line BL is set low (e.g., VSS) during the write “0” operation, the internal storage node BLTI will begin to discharge to VSS through pass gate transistor NPG_L. Transistor NPG_L will easily be able to discharge node BLTI since this node will be floating, with transistor PPU_L1 disconnected from VDD. Hence, write assist circuit 304 facilitates the discharging of the internal storage node BLTI during the write “0” operation. Recall, that in the illustrative 6T SRAM cell 200 shown in FIG. 2, transistor PPU_L1 is directly connected to VDD, and thus the pass gate transistor NPG_L must be sized appropriately to overcome the opposition from PPU_L1 attempting to pull node BLTI up to VDD during a write “0” operation. Once the internal storage node BLTI discharges to about a PMOS threshold voltage below VDD, the complementary internal storage node BLFI will be pulled high by the latch action of the storage element 302. Using this write assist approach according to one or more embodiments of the invention, transistors in storage element 302 (e.g., PPU_L1, PPU_R1, NPD_L and NPD_R) need not be sized for write margin; rather, these transistors can be sized appropriately to favor improved SNM. It is to be understood that the term “sized” as used herein is intended to refer broadly to the selection of a channel width (W) and/or channel length (L) of a given transistor device. As is known by those skilled in the art, a ratio of channel width to channel length (W/L) of a transistor device affects drive strength of the device.

A write “1” operation of SRAM cell 400 would be performed in manner consistent with the write “0” operation previously described. During the write “1” operation, however, bit line BL remains at its precharged high level (e.g., VDD), and complementary bit line BLB is set to a low level (e.g., VSS). As in the case of the write “0” operation, the word lines WL and WLB are asserted by setting WL high and WLB low, thereby turning on pass gate transistors NPG_L, NPG_R, PPG_L and PPG_R. With word line WL asserted high, pull-up transistors PPU_L2 and PPU_R2 are turned off, thereby effectively disconnecting the storage element 302 (particularly, transistors PPU_L1 and PPU_R1) from the voltage supply VDD. With PPG_R turned on and PPU_R2 turned off, the node BLFI_int will begin discharging to VSS through pass gate PPG_R. Once the voltage at node BLFI_int falls below about a PMOS transistor threshold voltage (Vtp) above VSS, transistor PPU_R1 in the storage element 302 will completely turn off, thereby causing the internal storage node BLFI to float, since there will be no current flowing through transistors PPU_R1 and NPD_R. With bit line BL being set to a logic high level and with the complementary word line WLB at a low level, pass gate transistor PPG_L will be turned on. Accordingly, node BLTI_int will remain pulled up to VDD through transistor PPG_L for supplying power to the inverter comprising transistors PPU_L1 and NPD_L.

Since bit line BLB is set low (e.g., VSS) during the write “1” operation, the internal storage node BLFI will begin discharging to VSS through pass gate transistor NPG_R. Transistor NPG_R will easily be able to discharge node BLFI since this node will be floating, with transistor PPU_R1 disconnected from VDD. Hence, write assist circuit 304 facilitates the discharging of the internal storage node BLFI during the write “1” operation. Once the internal storage node BLFI discharges to about a PMOS threshold voltage below VDD, the complementary internal storage node BLTI will be pulled high by the latch action of the storage element 302.

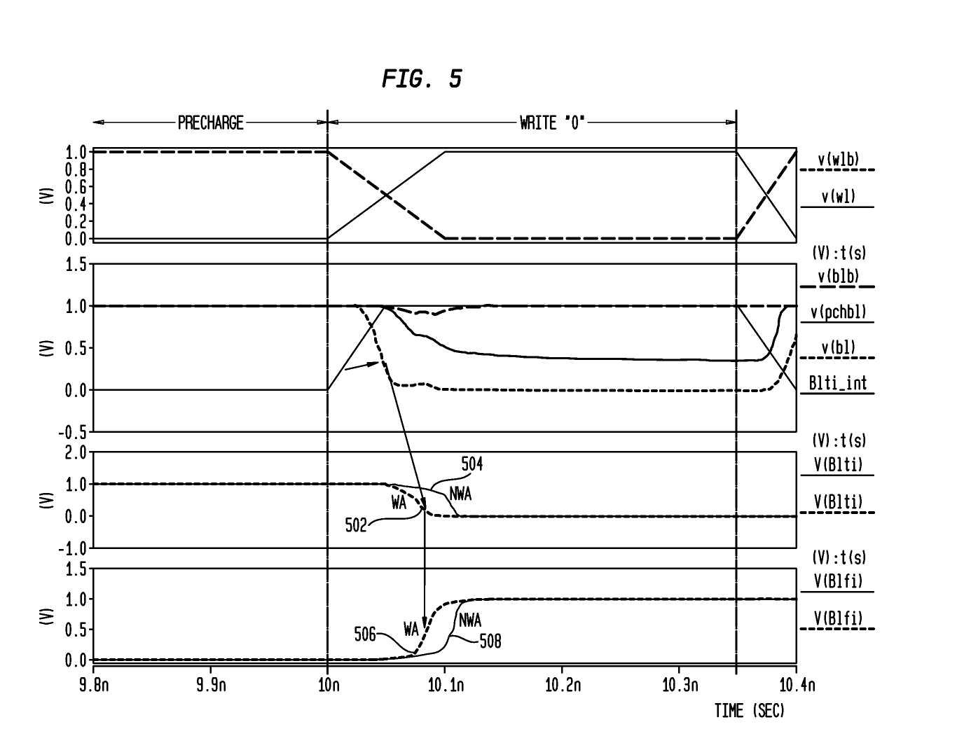

FIG. 5 is graph depicting exemplary waveforms corresponding to certain signals in the SRAM cell 400 shown in FIG. 4, according to an embodiment of the invention. For comparison purposes, the internal storage nodes BLTI and BLFI for a 6Tare also shown. As shown in FIG. 5, up until about 10.0 nanosecond (ns), the SRAM cell 400 is in a precharge state, where the precharge control signal PCHBL is asserted low and both bit lines BL and BLB are precharged high. During this precharge period, the word line WL and the complementary word line WLB are de-asserted (WL is low and WLB is high). After about 10.0 ns, the precharge control signal PCHBL is de-asserted high, indicating an end of the precharge phase. With PCHBL de-asserted, a voltage is allowed to develop on the respective bit lines BL and BLB which is indicative of the data to be written into the memory cell. In this example, bit line BL is set to a logic low level for the write “0” operation. Concurrently, the word line WL is asserted high, marking a start of the write operation.

As apparent from FIG. 5, as the bit line BL discharges to VSS, the node BLTI_int discharges to about a PMOS threshold voltage below VDD; at this point, the pass gate transistor PPG_L has insufficient drive to discharge node BLTI_int further without turning off. As previously described, transistor PPU_L1 turns off and internal storage node BLTI discharges to VSS through pass gate NPG_L essentially unopposed, as indicated by waveform 502. For comparison purposes, waveform 504 is indicative of the voltage at internal storage node BLTI in an illustrative 6T SRAM cell (e.g., SRAM cell 200 shown in FIG. 2) without write assist functionality. Likewise, waveforms 506 and 508 are indicative of the voltages at internal storage node BLFI for SRAM cell 400 and an illustrative 6T SRAM cell without write assist functionality, respectively. It is apparent from FIG. 5 that the discharge rate for node BLTI and the charge rate for node BLFI for the SRAM cell 400 are significantly faster relative to the discharge and charge rates for an SRAM cell without write assist functionality.

Advantageously, the addition of the write assist circuitry 304 and corresponding pass gate transistors PPG_L and PPG_R to the SRAM cell 400 does not noticeably affect a read operation in the cell. By way of example only, with reference again to FIG. 4, assume a logic “0” is stored in SRAM cell 400. As such, internal storage node BLTI will be at a logic low level (e.g., VSS) and node BLFI will be at a logic high level (e.g., VDD). During the read operation, the word lines are asserted by setting WL high and setting WLB low, thereby turning on pass gate transistors NPG_L, NPG_R, PPG_L and PPG_R and discharging either bit line BL or bit line BLB to VSS based on the data stored in the SRAM cell 400. Since, in this example, a logic “0” is stored in the SRAM cell 400 (i.e., node BLTI is at VSS and node BLFI is at VDD), bit line BL will begin discharging through NPG_L, and bit line BLB will remain at its precharged high level. Since PPU_L2 and PPU_R2 are turned off, as a result of the word line WL being high, the nodes BLTI_int and BLFI_int will receive power from the precharged bit lines BL and BLB through respective pass gate transistors PPG_L and PPG_R, since WLB has gone low, rather than through PPU_L2 and PPU_R2. Consequently, a standard read operation will ensue.

Since node BLTI_int receives power from bit line BL (via transistor PPG_L), which will be discharging during the read “0” operation, a question may be raised as to whether node BLTI_int will be disturbed by the discharging of the bit line BL. However, upon further consideration, it can be shown that this situation does not present any problem during the read “0” operation. Specifically, during a read “0” operation, transistor PPU_L1 is turned off, with its gate at VDD, so there is no impact of the stability of the SRAM cell 400. Furthermore, in a standard memory device, the bit lines are not discharged below about 100 millivolts (mV), so that transistor PPG_L will always be turned off. Even if the bit line is discharged to VSS, transistor PPU_L1 will always remain off.

Since the storage element 302 in the illustrative SRAM cell 400 is preferably sized for improved SNM stability, the cell is able to provide multiplexing (MUX) support without any additional circuitry. Multiplexing is a known technique used in some memory devices to improve an aspect ratio of the memory device. In this technique, more than one of the memory cells can use the same I/O gating sense amplifier.

By way of illustration only and without limitation, consider a memory array having four memory cells. There are three ways in which the four memory cells can be arranged in the memory array. A first way is to configure the memory array such that all four memory cells reside in single column. In this scenario, the memory array would require four word lines and a single bit line. Another way is to configure the memory array such that all four memory cells reside in single row. In this scenario, the memory array would require a single word line and four different bit lines. A third way is to configure the memory cells as a 2×2 arrangement, wherein two memory cells reside in a first row and two memory cells reside in a second row. In this scenario, the memory array would require two word lines and two bit lines.

The first approach, where all the memory cells are arranged in single column, will result in a higher capacitive load on the bit line and a minimal capacitive load on the four word lines compared to the other configurations. Alternatively, the second approach, where all the memory cells are arranged in a single row, will result in a higher capacitive load on the word line and a minimal capacitive load on the four word lines compared to the other two configurations. The third approach achieves a more even distribution of capacitive load among the word lines and bit lines compared to the other memory configurations. This results in better optimization of memory access and cycle time.

The first approach is a non-multiplexing arrangement of memory cells. Therefore, depending on which of the four word lines is selected, data is read from or written into a given memory cell. The rest of the non-selected memory cells are not disturbed at all, as the respective word lines corresponding to the non-selected memory cells are not asserted (i.e., not turned on). In the second approach, however, wherein a single word line is used for all memory cells, when the word line is asserted to access (e.g., read or write) a selected one of the memory cells, all of the memory cells are placed into an access mode. If only a single memory cell is to be read, the remaining three memory cells will be in a static noise margin mode, which can be defined herein as a state in which the word line corresponding to a given memory cell is asserted (i.e., turned on) and the bit lines corresponding to those memory cells are in a precharge state. With a conventional memory cell subjected to this scenario, data stored therein is likely to be disturbed, and therefore invalid. A memory cell that is configured to be stable for SNM, according to embodiments of the invention, will be immune from data disturbs in this scenario.

Similarly, in the third approach having two memory cells in a first row and two memory cells in a second row, depending on the row selected, if a first memory cell is being read/written, a second memory cell in the same row will be in static noise margin mode. Thus, as described above, the second memory cell should be designed to be SNM stable; otherwise, data corruption as a result of disturbs are likely. Accordingly, if multiplexing is a desired characteristic for a memory device (e.g., for improving an aspect ratio of the memory device), it is important for the memory cells to be configured having increased SNM stability.

Similarly, in memory devices where bit-mask options are supported (which allows selective write on prescribed bits in the memory cells), when a bit is masked from writing, it is subjected to SNM conditions, since the corresponding word line will be asserted and the masked bit line will be in a precharged mode. Thus, to prevent corruption of data stored in the memory cells, the memory cells should be configured to be SNM stable. To size a memory cell for SNM stability, the cell should be free from write margin issues. This has been difficult to achieve in the past since write margin and SNM are often mutually exclusive properties of a memory cell, as previously stated. However, write assist circuitry according to one or more embodiments of the invention enhances memory cell writability, so that designers are free to configure the memory cell for improved SNM stability.

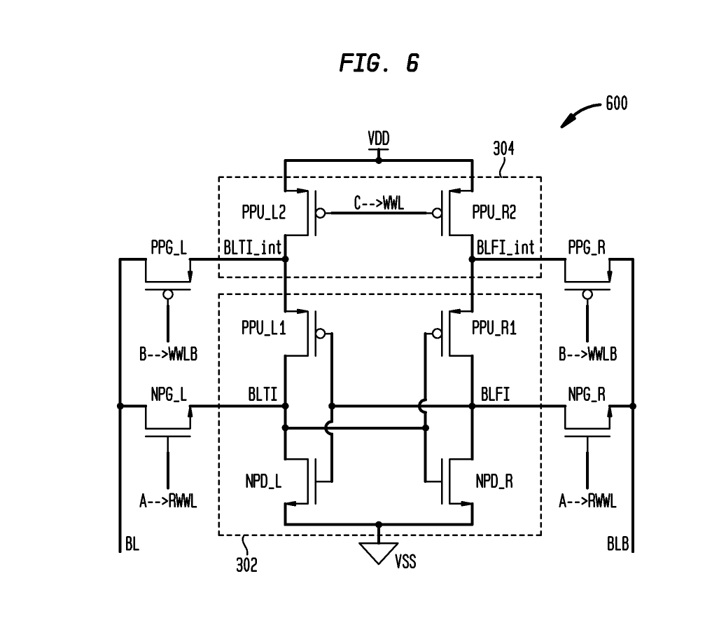

FIG. 6 is a schematic diagram depicting at least a portion of an exemplary SRAM memory cell 600 with built-in write assist functionality, according to another embodiment of the invention. SRAM cell 600 is suitable for use in a memory device/system having one or more read/write word lines, RWWL, and complementary write word lines, WWL and WWLB, rather than a single set of word lines WL. Like the SRAM cell 400 shown in FIG. 4, SRAM cell 600 comprises essentially the same circuit architecture as the exemplary SRAM cell 300 shown in FIG. 3, except that connections to nodes A, B and C are depicted, in accordance with another illustrative embodiment of the invention. Specifically, node A is connected with a corresponding read/write word line, RWWL, node C is connected with a corresponding write word line, WWL, and node B is connected with a logical complement (i.e., a logical inversion) of the write word line, WWLB.

In terms of operation, during a default (i.e., initial) state of the SRAM cell 600, such as when the cell is not being accessed in conjunction with a read or write operation, the read/write word line RWWL will be at a logic low level (i.e., de-asserted), the write word line WWL will be at a logic low level, the complementary write word line WWLB will be at a logic high level, and the complementary bit lines BL and BLB will be precharged to a logic high level (e.g., VDD), in this example. With the read/write word line RWWL at a logic low level (e.g., VSS), NFET devices NPG_L and NPG_R will be turned off, thereby disconnecting the internal storage nodes BLTI and BLFI from the bit lines BL and BLB, respectively. Moreover, with the write word line WWL at a logic low level and the complementary write word line WWLB at a logic high level, PFET devices PPU_L2 and PPU_R2 will be turned on, and PFET devices PPG_L and PPG_R will be turned off, thereby allowing nodes BLTI_int and BLFI_int to be pulled high (e.g., VDD). The voltage levels on the internal storage nodes BLTI and BLFI will determine the state of the SRAM cell 600. Thus, in the case of a logic “1” being stored in the SRAM cell 600, node BLTI is presumed to be high (e.g., VDD) and node BTFI is presumed to be low (e.g., VSS).

During a write operation, at the start of the write operation, one of the precharge control signals, PCHBL or PCHBLB (see FIG. 4), will be de-asserted (i.e., PCHBL or PCHBLB will go high), thereby forcing the corresponding one of the complementary bit lines BL or BLB, respectively, low (e.g., VSS), depending on whether a write “0” or a write “1” operation is performed. Substantially concurrently, the read/write word line RWWL and the complementary write word lines WWL and WWLB are asserted by setting RWWL and WWL high and setting WWLB low, thereby turning on pass gate transistors PPG_L, PPG_R, NPG_L and NPG_R, and turning off pull-up transistors PPU_L2 and PPU_R2. With PPU_L2 and PPU_R2 turned off, the storage element 302 is effectively disconnected from the voltage supply VDD.

In the case of a write “0” operation, bit line BL will be forced low (e.g., VSS) and bit line BLB will remain at its precharged high level (e.g., VDD). With PPG_L turned on and PPU_L2 turned off, node BLTI_int will begin discharging to VSS through pass gate PPG_L. Once the voltage at node BLTI_int falls below about a PMOS transistor threshold voltage (Vtp) above VSS, transistor PPU_L1 will completely turn off, thereby causing the internal storage node BLTI to float, since there will be no current flowing through transistors PPU_L1 and NPD_L. Since bit line BL is set low during the write “0” operation, the internal storage node BLTI will begin to discharge to VSS through pass gate transistor NPG_L. Transistor NPG_L will easily be able to discharge node BLTI since this node will be floating, with transistor PPU_L1 disconnected from VDD. Once the internal storage node BLTI discharges to about a PMOS transistor threshold voltage below VDD, the complementary internal storage node BLFI will be pulled high by the latch action of the storage element 302. In this manner, write assist circuit 304 facilitates the discharging of the internal storage node BLTI during the write “0” operation.

Similarly, in the case of a write “1” operation, bit line BLB will be forced low and bit line BL will remain at its precharged high level. With PPG_R turned on and PPU_R2 turned off, node BLFI_int will begin discharging to VSS through pass gate PPG_R. Once the voltage at node BLFI_int falls below about a PMOS transistor threshold voltage above VSS, transistor PPU_R1 will completely turn off, thereby causing the internal storage node BLFI to float. Since bit line BLB is set low during the write “1” operation, the internal storage node BLFI will begin discharging to VSS through pass gate transistor NPG_R. Transistor NPG_R will easily be able to discharge node BLFI since this node will be floating, with transistor PPU_R1 disconnected from VDD. Hence, write assist circuit 304 facilitates the discharging of the internal storage node BLFI during the write “1” operation. Once the internal storage node BLFI discharges to about a PMOS threshold voltage below VDD, the complementary internal storage node BLTI will be pulled high by the latch action of the storage element 302.

In the case of a read operation, read/write word line RWWL will be asserted by setting RWWL to a high level. The complementary write word lines WWL and WWLB will remain at their default values; namely, WWL will remain at a low level and WWLB will remain at a high level. Voltage levels for the read/write word line RWWL and complementary write word lines WWL and WWLB are preferably generated by row circuitry in the memory device, such as, for example, a row decoder (e.g., row decoder 125 shown in FIG. 1). The read operation for SRAM cell 600 is performed in a conventional manner.

As previously stated, the memory cell with built-in write assist functionality according to one or more embodiments of the invention can be adapted for use in a variety of memory devices or systems. For example, although embodiments of an SRAM cell with built-in write assist functionality have been described herein in conjunction with FIGS. 3 through 6 for use in a single-port memory device application, embodiments of the invention can also be adapted for use in a multi-port memory system application.

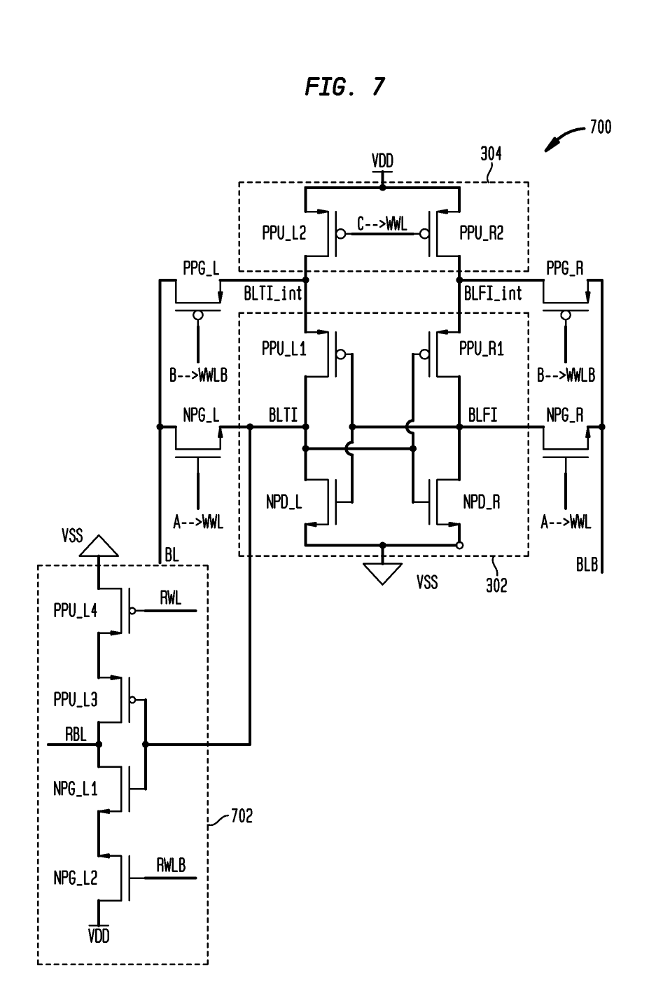

By way of example only and without limitation, FIG. 7 is a schematic diagram depicting at least a portion of an SRAM cell 700 with built-in write assist functionality adapted for use in a dual-port memory architecture, according to an embodiment of the invention. The SRAM cell 700 is configured for use in a memory system comprising separate read and write word lines and bit lines; namely, complementary read word lines, RWL and RWLB, complementary write word lines, WWL and WWLB, a read bit line, RBL, and complementary write bit lines, BL and BLB.

The SRAM cell 700, like SRAM cell 300 shown in FIG. 3, includes a storage element 302 comprised of a pair of cross-coupled inverters, and first switching circuitry comprising first and second NFETs, NPG_L and NPG_R, operative as pass gate devices, for selectively connecting the storage element to respective complementary write bit lines BL and BLB. More particularly, a first inverter includes PFET PPU_L1 and NFET NPD_L, and a second inverter includes PFET PPU_R1 and NFET NPD_R. A drain of NPG_L is coupled with write bit line BL, a gate of NPG_L is adapted to receive a first control signal at node A, and a source of NPG_L is connected with drains of PPU_L1 and NPD_L at node BLTI. Sources of NPD_L and NPD_R are adapted for connection with a voltage return of the SRAM cell, which in this embodiment is VSS, gates of PPU_L1 and NPD_L are connected with drains of PPU_R1 and NPD_R at node BLFI, and gates of PPU_R1 and NPD_R are connected to node BLTI. A gate of NPG_R is connected with node A and is adapted to receive the first control signal, a drain of NPG_R is connected with node BLFI, and a source of NPG_R is coupled with complementary write bit line BLB. When the first control signal is at a logic high level (e.g., VDD), the internal storage nodes BLTI and BLFI in storage element 302 are connected to corresponding write bit lines BL and BLB through pass gates NPG_L and NPG_R, respectively. Likewise, when the first control signal is at a logic low level (e.g., VSS), devices NPG_L and NPG_R turn off, thereby electrically disconnecting the storage element 302 from the write bit lines BL and BLB. In this illustrative embodiment, node A is adapted for connection with corresponding write word line WWL.

The SRAM cell 700 includes write assist circuitry 304 connected between the storage element 302 and a voltage supply of the SRAM cell, which in this embodiment is VDD, and second switching circuitry comprising first and second PFETs, PPG_L and PPG_R, operative as pass gate devices, for selectively connecting the write assist circuitry to respective complementary write bit lines BL and BLB. In this embodiment, the write assist circuitry 304 comprises a pair of PFET pull-up devices, PPU_L2 and PPU_R2, although embodiments of the invention are not limited to the particular circuit arrangement shown. Specifically, a drain of PPG_L is connected with bit line BL, a gate of PPG_L is adapted to receive a second control signal at node B, and a source of PPG_L is connected with a source of PPU_L1 and a drain of PPU_L2 at node BLTI_int. A drain of PPG_R is connected with bit line BLB, a gate of PPG_R is connected with node B and is adapted to receive the second control signal, and a source of PPG_R is connected with a source of PPU_R1 and a drain of PPU_R2 at node BLFI_int. Sources of PPU_L2 and PPU_R2 are adapted for connection with VDD, and gates of PPU_L2 and PPU_R2 are adapted to receive a third control signal at node C. In this illustrative embodiment, node B is adapted for connection with a corresponding complementary write word line, WWLB, and node C is adapted for connection with the write word line WWL. Hence, the write port circuitry of SRAM cell 700, including pass gates PPG_L, PPG_R, NPG_L and NPG_R, is operative in a manner consistent with that previously described.

SRAM cell 700 further includes dedicated read port circuitry 702, which in this embodiment is inverter-based. The read port circuitry is independently asserted as a function of at least one read control signal. Specifically, the read port circuitry 702 comprises a first NFET device, NPG_L1, a second NFET device, NPG_L2, a first PFET device, PPU_L3, and a second PFET device, PPU_L4. The NFET NPG_L1 and PFET PPU_L3 are connected as an inverter, with NFET NPG_L2 and PFET PPU_L4 being used as switching devices for selectively connecting the inverter to VDD and VSS, respectively. More particularly, drains of NPG_L1 and PPU_L3 are connected with the corresponding read bit line RBL, gates of NPG_L1 and PPU_L3 are connected with internal storage node BLTI, a source of NPG_L1 is connected with a source of NPG_L2, and a source of PPU_L3 is connected with a source of PPU_L4. A drain of NPG_L2 is adapted for connection with VDD, a gate of NPG_L2 is connected with corresponding complementary read word line RWLB, a drain of PPU_L4 is adapted for connection with VSS, and a gate of PPU_L4 is connected with corresponding read word line RWL. In one or more other embodiments, the inverter (comprised of transistors NPG_L1 and PPU_L3) may be replaced by a driver circuit, which can be inverting or non-inverting.

During a read operation, which is dedicated and may be performed concurrently with a write operation, the complementary read word lines RWL and RWLB are asserted by setting RWL to a logic high level (e.g., VDD) and RWLB to a logic low level (e.g., VSS). By asserting the read word lines RWL and RWLB, switching devices PPU_L4 and NPG_L2 will turn on, thereby connecting the inverter comprising transistors PPU_L3 and NPG_L1 to VDD and VSS, respectively. Thus, the read bit line RBL will be driven by the inverter in read port circuitry 702 to a voltage level that is indicative of a state of the storage element 302. For example, assuming the storage element 302 is storing a logic “1,” internal storage node BLTI will be at a logic high level and the read bit line RBL will be at a logic low level; the opposite would be true if the storage element 302 were storing a logic “0.” The state of the read bit line is detected by column circuitry, such as, for example, a corresponding sense amplifier (e.g., I/O gating sense amplifier 135 shown in FIG. 1). During a write operation, the complementary read word lines RWL and RWLB are de-asserted by setting RWL to a logic low level and RWBL to a logic high level, thereby disabling the inverter in the read port circuitry 702.

As apparent from FIG. 7, modifying a single-port SRAM cell with write assist functionality (e.g., SRAM cell 600 shown in FIG. 6) for use in a multi-port memory system, according to one or more embodiments of the invention, involves adding minimal read port circuitry. Like SRAM cells 300-600 described above, SRAM 700 exhibits improved SNM stability without write margin issues. Furthermore, embodiments of the invention achieve such performance improvements without significantly impacting read speed or increasing chip area.

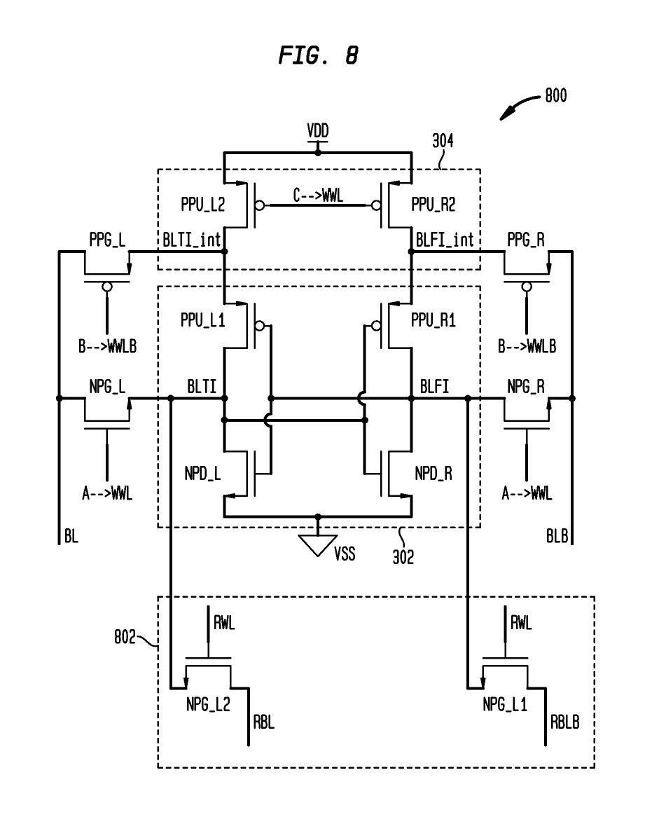

With reference now to FIG. 8, at least a portion of an exemplary SRAM cell 800 with built-in write assist functionality adapted for use in a dual-port memory architecture is shown, according to another embodiment of the invention. SRAM cell 800, like the illustrative SRAM cell 700 shown in FIG. 7, is configured for use in a memory system comprising separate read and write word lines and bit lines. Specifically, the SRAM cell 800 is configured for use in a memory system including corresponding complementary write word lines, WWL and WWLB, complementary write bit lines, BL and BLB, a read word line, RWL, and complementary read bit lines, RBL and RBLB.

Write port circuitry in the SRAM cell 800 is essentially implemented, in this embodiment, in a manner consistent with the write port circuitry in the SRAM cell 700 shown in FIG. 7. Specifically, SRAM cell 800 comprises a storage element 302 comprised of a pair of cross-coupled inverters, and first switching circuitry comprising first and second NFETs, NPG_L and NPG_R, operative as pass gate devices, for selectively connecting the storage element to respective complementary write bit lines BL and BLB. The SRAM cell 800 includes write assist circuitry 304 connected between the storage element 302 and a voltage supply of the SRAM cell, which in this embodiment is VDD, and second switching circuitry comprising first and second PFETs, PPG_L and PPG_R, operative as pass gate devices, for selectively connecting the write assist circuitry to respective complementary write bit lines BL and BLB. As previously described, the write assist circuitry 304 comprises a pair of PFET pull-up devices, PPU_L2 and PPU_R2, although embodiments of the invention are not limited to the particular circuit arrangement shown. In this illustrative embodiment, as in SRAM cell 700, gates of devices NPG_L and NPG_R, as well as gates of the pull-up devices PPU_L2 and PPU_R2 in the write assist circuitry 304, are connected with a corresponding write word line WWL, and gates of devices PPG_L and PPG_R are connected with corresponding complementary write word line WWLB. Hence, the write port circuitry in SRAM cell 800, including pass gates PPG_L, PPG_R, NPG_L and NPG_R, is operative in a manner consistent with that previously described in conjunction with illustrative SRAM cell 700.

SRAM cell 800 further includes dedicated read port circuitry 802. In comparison to the read port circuitry 702 in the exemplary SRAM cell 700, which was inverter-based and single-ended, read port circuitry 802 is based on a pair of pass gates and is differential in topology. Specifically, the read port circuitry 802 comprises a first NFET device, NPG_L1, and a second NFET device, NPG_L2. A drain of NPG_L2 is adapted for connection with corresponding read bit line RBL, a source of NPG_L2 is connected with internal storage node BLTI, and a gate of NPG_L2 is adapted for connection with corresponding read word line RWL. Similarly, a drain of NPG_L1 is adapted for connection with corresponding complementary read bit line RBLB, a source of NPG_L1 is connected with internal storage node BLFI, and a gate of NPG_L1 is adapted for connection with the read word line RWL.

During a read operation, which is dedicated and may be performed concurrently with a write operation, the complementary read word line RWL is asserted by setting RWL to a logic high level (e.g., VDD). By asserting the read word line RWL, pass gate devices NPG_L1 and NPG_L2 will turn on, thereby connecting the internal storage nodes BLTI and BLFI with the read bit lines RBL and RBLB, respectively. The read bit lines RBL and RBLB will be driven to voltage levels that are indicative of a state of the storage element 302. For example, assuming the storage element 302 is storing a logic “1,” internal storage node BLTI will be at a logic high level, the read bit line RBL will be driven to a logic high level and the complementary read bit line RBLB will be drive to a logic low level; the opposite would be true if the storage element 302 were storing a logic “0.” The state of the read bit lines are detected by column circuitry, such as, for example, a corresponding sense amplifier (e.g., I/O gating sense amplifier 135 shown in FIG. 1). During a write operation, the read word line RWL is de-asserted by setting RWL to a logic low level, thereby electrically disconnecting the read port circuitry 802 from the complementary read bit lines RBL and RBLB.

Multiple embodiments of an SRAM cell with built-in write assist functionality are shown and described herein, by way of example only and without limitation. However, while specific illustrative circuit arrangements are shown in FIGS. 3 through 8, it is to be appreciated that numerous other modifications to the SRAM cell with built-in write assist functionality are contemplated, in accordance with embodiments of the invention, that enable the SRAM cell to be used in a variety of single-port and multi-port memory architectures and applications, as will become apparent to those skilled in the art given the teachings herein. Moreover, as apparent from FIGS. 7 and 8, for example, write port circuitry can remain the same, and read port circuitry would not require any significant additional components or circuit complexity.

It should be understood that the use of PMOS and NMOS transistor devices in the particular memory cell embodiments shown in the figures and described herein above are by way of illustration only. In other embodiments, the conductivity type of each of certain transistor devices in the memory cell may be substituted with a transistor device having a reverse conductivity type. For example, a PMOS device may be replaced by an NMOS device, with a logical complement of a control signal supplied to the PMOS device being supplied to the NMOS device, as will become apparent to those skilled in the art.

A given memory cell and/or memory device configured in accordance with one or more embodiments of the invention may be implemented as a standalone memory device, for example, as a packaged integrated circuit (IC) memory device suitable for incorporation into a higher-level circuit board or other system. Alternatively, one or more embodiments of the invention may be implemented as an embedded memory device, where the memory may be, for example, embedded into a processor or other type of integrated circuit device which comprises additional circuitry coupled with the memory device. More particularly, a memory device as described herein may comprise an embedded memory implemented within a microprocessor, digital signal processor (DSP), application-specific integrated circuit (ASIC), field-programmable gate array (FPGA), or other type of processor or integrated circuit device.

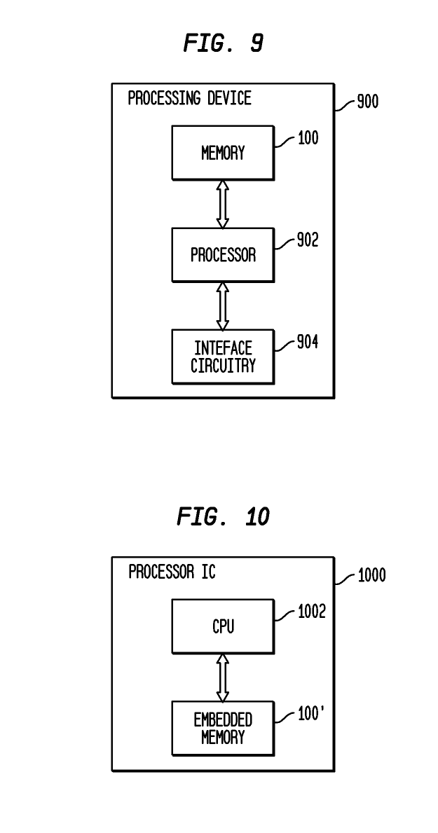

FIG. 9 is a block diagram depicting at least a portion of an exemplary processing device 900 which incorporates the illustrative memory device 100 of FIG. 1, according to an embodiment of the invention. In this embodiment, the memory device 100, which comprises one or more memory cells configured in accordance with one or more embodiments of the invention, is coupled with a processor 902. The processing device 900 further includes interface circuitry 904 coupled with the processor 902. The processing device 900 may comprise, for example, a computer, a server, a communication device, including, but not limited to, a mobile phone or tablet device, etc. The interface circuitry 904 may comprise one or more transceivers for allowing the processing device 900 to communicate over a network or other communication channel.

Alternatively, processing device 900 may comprise a microprocessor, DSP or ASIC, with processor 902 corresponding to a central processing unit (CPU) and memory device 100 providing at least a portion of an embedded memory of the microprocessor, DSP or ASIC. By way of example only and without limitation, FIG. 10 is a block diagram depicting at least a portion of an exemplary processor integrated circuit 1000 incorporating the memory device of FIG. 1 as an embedded memory 100′, according to an embodiment of the invention. The embedded memory 100′ in this embodiment is coupled with a CPU 1002.

In an integrated circuit implementation of one or more embodiments of the invention, multiple identical die are typically fabricated in a repeated pattern on a surface of a semiconductor wafer. Each such die may include a device described herein, and may include other structures and/or circuits. The individual dies are cut or diced from the wafer, then packaged as integrated circuits. One skilled in the art would know how to dice wafers and package die to produce integrated circuits. Any of the exemplary circuits illustrated in the accompanying figures, or portions thereof, may be part of an integrated circuit. Integrated circuits so manufactured are considered part of this invention.

The illustrations of embodiments of the invention described herein are intended to provide a general understanding of the structure of various embodiments, and they are not intended to serve as a complete description of all the elements and features of apparatus and systems that might make use of the structures described herein. Many other embodiments will become apparent to those skilled in the art given the teachings herein; other embodiments are utilized and derived therefrom, such that structural and logical substitutions and changes can be made without departing from the scope of this disclosure. The drawings are also merely representational and are not drawn to scale. Accordingly, the specification and drawings are to be regarded in an illustrative rather than a restrictive sense.

Embodiments of the invention are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The abstract is provided to comply with 37 C.F.R. §1.72(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, inventive subject matter lies in less than all features of a single embodiment. Thus the following claims are hereby incorporated into the Detailed Description, with each claim standing on its own as separately claimed subject matter.

Given the teachings of embodiments of the invention provided herein, one of ordinary skill in the art will be able to contemplate other implementations and applications of the techniques of embodiments of the invention. Although illustrative embodiments of the invention have been described herein with reference to the accompanying drawings, it is to be understood that embodiments of the invention are not limited to those precise embodiments, and that various other changes and modifications are made therein by one skilled in the art without departing from the scope of the appended claims.

What is claimed is:

1. A memory cell, comprising:
a storage element for storing a logical state of the memory cell;
first switching circuitry operative to selectively couple at least one internal storage node of the storage element with a corresponding bit line as a function of a first control signal;
write assist circuitry coupled between a supply node of at least one device of the storage element and a voltage supply of the memory cell; and
second switching circuitry operative to selectively couple the supply node of the at least one device of the storage element with the corresponding bit line as a function of a second control signal;
wherein during a write operation of the memory cell, the write assist circuitry is operative to disconnect the storage element from the voltage supply of the memory cell and the second circuitry is operative to connect the supply node of the at least one device of the storage element with the corresponding bit line.

2. The memory cell of claim 1, wherein the write assist circuitry comprises first and second transistor devices, a first source/drain of the first and second transistor devices being adapted for connection with the voltage supply of the memory cell, a second source/drain of the first transistor device being connected with a first supply node of a first device of the storage element, a second source/drain of the second transistor device being connected with a second supply node of a second device of the storage element, and gates of the first and second transistor devices being adapted to receive a third control signal, the third control signal being operative to disconnect the storage element from the voltage supply of the memory cell during a write operation of the memory cell.

3. The memory cell of claim 2, wherein the first and third control signals are conveyed by a corresponding word line of the memory cell and the second control signal is conveyed by a corresponding complementary word line of the memory cell.

4. The memory cell of claim 2, wherein the first control signal is conveyed by a corresponding read/write word line of the memory cell, the second control signal is conveyed by a corresponding complementary write word line of the memory cell, and the third control signal is conveyed by a corresponding write word line of the memory cell.

5. The memory cell of claim 2, wherein the first and third control signals are conveyed by a corresponding write word line of the memory cell and the second control signal is conveyed by a corresponding complementary write word line of the memory cell.

6. The memory cell of claim 1, further comprising read port circuitry, the read port circuitry being independently asserted as a function of at least one read control signal supplied to the memory cell.

7. The memory cell of claim 6, wherein the read port circuitry is operative as a function of the at least one read control signal to selectively couple the at least one internal storage node of the storage element with at least one corresponding read bit line.

8. The memory cell of claim 6, wherein the read port circuitry comprises first and second switches and a driver circuit, the driver circuit including an input coupled to the internal storage node of the storage element and including an output for driving a corresponding read bit line, the first and second switches being operative to selectively connect the driver circuit with the voltage supply of the memory cell as a function of the at least one read control signal.

9. The memory cell of claim 6, wherein the read port circuitry comprises switching circuitry operative to selectively connect the internal storage node of the storage element with a corresponding read bit line as a function of the at least one read control signal.

10. The memory cell of claim 1, wherein the storage element comprises a pair of cross-coupled inverters configured as a latch, and wherein the write assist circuitry is coupled between a supply node of a device of at least one of the cross-coupled inverters in the storage element and the voltage supply of the memory cell.

11. The memory cell of claim 1, wherein the storage element comprises first and second internal storage nodes, the second internal storage node being a logical complement of the first internal storage node, and wherein the first switching circuitry comprises first and second transistor devices, a first source/drain of the first transistor device being coupled with the corresponding bit line of the memory cell, a second source/drain of the first transistor device being connected with the first internal storage node, a first source/drain of the second transistor device being coupled with a corresponding complementary bit line of the memory cell, a second source/drain of the second transistor device being connected with the second internal storage node, and gates of the first and second transistor devices being adapted to receive the first control signal.

12. The memory cell of claim 1, wherein the storage element comprises first and second supply nodes of first and second devices, respectively, of the storage element, and wherein the second switching circuitry comprises first and second transistor devices, a first source/drain of the first transistor device being coupled with the corresponding bit line of the memory cell, a second source/drain of the first transistor device being connected with the first supply node of the storage element, a first source/drain of the second transistor device being coupled with a corresponding complementary bit line of the memory cell, a second source/drain of the second transistor device being connected with the second supply node of the storage element, and gates of the first and second transistor devices being adapted to receive the second control signal.

13. The memory cell of claim 1, wherein at least a portion of the memory cell is fabricated in at least one integrated circuit.

14. A memory device, comprising:
a plurality of memory cells;
at least one word line and a plurality of bit lines, the word line and bit lines being coupled with the memory cells for individually accessing the memory cells;
wherein at least a given one of the memory cells comprises:
a storage element for storing a logical state of the memory cell;
first switching circuitry operative to selectively couple at least one internal storage node of the storage element with a corresponding one of the bit lines as a function of a first control signal;
write assist circuitry coupled between a supply node of at least one device of the storage element and a voltage supply of the memory cell; and
second switching circuitry operative to selectively couple the supply node of the at least one device of the storage element with the corresponding one of the bit lines as a function of a second control signal;
wherein during a write operation of the memory cell, the write assist circuitry is operative to disconnect the storage element from the voltage supply of the memory cell and the second circuitry is operative to connect the supply node of the at least one device of the storage element with the corresponding bit line.

15. The memory device of claim 14, wherein the write assist circuitry in the given one of the memory cells comprises first and second transistor devices, a first source/drain of the first and second transistor devices being adapted for connection with the voltage supply of the memory cell, a second source/drain of the first transistor device being connected with a first supply node of a first device of the storage element in the given one of the memory cells, a second source/drain of the second transistor device being connected with a second supply node of a second device of the storage element in the given one of the memory cells, and gates of the first and second transistor devices being adapted to receive a third control signal, the third control signal being operative to disconnect the storage element from the voltage supply of the memory cell during a write operation of the memory cell.

16. The memory device of claim 15, wherein the first and third control signals are conveyed by the at least one word line corresponding to the given one of the memory cells and the second control signal is conveyed by a corresponding complementary word line of the memory cell.

17. The memory device of claim 14, wherein the given one of the memory cells further comprises read port circuitry, the read port circuitry being independently asserted as a function of at least one read control signal supplied to the memory cell.

18. The memory device of claim 17, wherein the read port circuitry is operative as a function of the at least one read control signal to selectively couple the at least one internal storage node of the storage element with at least one corresponding read bit line in the memory device.

19. The memory device of claim 17, wherein the read port circuitry comprises first and second switches and a driver circuit, the driver circuit including an input coupled to the internal storage node of the storage element of the given one of the memory cells and including an output for driving a corresponding read bit line in the memory device, the first and second switches being operative to selectively connect the driver circuit with the voltage supply of the memory cell as a function of the at least one read control signal.

20. The memory device of claim 14, wherein the storage element in the given one of the memory cells comprises a pair of cross-coupled inverters configured as a latch, and wherein the write assist circuitry is coupled between a supply node of a device of at least one of the cross-coupled inverters in the storage element and the voltage supply of the memory cell.

21. The memory device of claim 14, further comprising precharge circuitry coupled to at least a subset of the plurality of bit lines, the precharge circuitry being operative, when memory cells coupled with the subset of the plurality of bit cells are not being accessed in conjunction with a read or write operation, to set the subset of the plurality of bit lines to a prescribed voltage level.

22. The memory device of claim 14, wherein the memory device comprises at least one of an embedded memory and a standalone memory.

23. A method for enhancing write performance in a memory cell, the method comprising:
providing at least one memory cell comprising a storage element for storing a logical state of the memory cell, first switching circuitry operative to selectively couple at least one internal storage node of the storage element with a corresponding bit line as a function of a first control signal, write assist circuitry coupled between a supply node of at least one device of the storage element and a voltage supply of the memory cell, and second switching circuitry operative to selectively couple the supply node of the at least one device of the storage element with the corresponding bit line as a function of a second control signal; and
during a write operation of the memory cell, configuring the write assist circuitry to disconnect the storage element from the voltage supply of the memory cell and configuring the second circuitry to connect the supply node of the at least one device of the storage element with the corresponding bit line.
